(19) United States
(12) Patent Application Publication
(10) Pub. No.: US 2018/0308687 A1
(43) Pub. Date: Oct. 25, 2018

(54) EUV PHOTOPATTERNING AND SELECTIVE DEPOSITION FOR NEGATIVE PATTERN MASK

(71) Applicant: Lam Research Corporation, Fremont, CA (US)

(72) Inventors: David Charles Smith, Lake Oswego, OR (US); Arpan Mahorowala, West Linn, OR (US)

(21) Appl. No.: 15/495,701

(22) Filed: Apr. 24, 2017

(51) Int. Cl. H01L 21/027; H01L 21/02; C23C 16/40; C23C 16/455; C23C 16/56; C23C 16/44; C23C 16/52

(52) U.S. Cl. CPC H01L 21/0274; H01L 21/0228; H01L 21/02164; C23C 16/405; C23C 16/52; C23C 16/402; C23C 16/56; C23C 16/4408; C23C 16/45544

(57) ABSTRACT

Process and apparatus for forming a negative patterning mask in the context of EUV patterning uses a selective deposition process to deposit a metal oxide or metal nitride thin film in a feature defined in an EUV resist to prepare a negative image for patterning. The method to produce the “negative” image does not involve an etch back step and therefore accommodates the small resist budget. The material forming the “negative” image is significantly more etch resistant than resist which eliminates the need for an additional hard mask transfer layer.

### FIELD OF THE DISCLOSURE

This disclosure relates generally to the field of semiconductor processing. In particular aspects, the disclosure is directed to process and apparatus for using selective deposition to form a negative patterning mask in the context of EUV patterning.

### BACKGROUND

Patterning of thin films in semiconductor processing is often a critical step in the fabrication of semiconductors. Patterning involves lithography. In conventional photolithography, such as 193 nm photolithography, patterns are printed by emitting photons from a photon source onto a mask and printing the pattern onto a photosensitive photoresist, thereby causing a chemical reaction in the photoresist that, after development, removes certain portions of the photoresist to form the pattern.

Advanced technology nodes (as defined by the International Technology Roadmap for Semiconductors) include nodes 22 nm, 16 nm, and beyond. In the 16 nm node, for example, the width of a typical via or line in a Damascene structure is typically no greater than about 30 nm. Scaling of features on advanced semiconductor integrated circuits (ICs) and other devices is driving lithography to improve resolution. One such approach is direct patterning of a photosensitive film, sometimes referred to as a EUV resist, with extreme ultraviolet (EUV) radiation.

Typical current EUV resists are polymer-based chemically amplified resists (CARs). Improvements in CARs have been made by reducing resist blur (acid diffusion) and pattern collapse by using thin films with high surface adhesion and structural integrity. Thin CARs, however, dictate process window and complexity necessitating the use of additional layers to support multi-step pattern transfer. Especially when the resist is thin, the pattern must be first transferred into a hard mask layer before subsequent transfer into the substrate.

The resist pattern is sometimes “inverted” by gapfilling the pattern with a spin on or vapor deposited film with adequate etch contrast. According to this conventional process, the gapfill operation is followed by an etch back step to remove gapfill material from the field region of the resist prior to resist strip. This approach is taken when the lithographic image contrast is superior for the “positive” pattern but the actual need is for the “negative” pattern. Etch back steps have limited selectivity resulting in the gapfill feature being shorter than optimal for a mask. This becomes even more critical when the resist is very thin e.g., EUV resist.

### SUMMARY

This disclosure provides method and apparatus for using a selective deposition process to deposit a metal oxide or metal nitride thin film in a feature defined in an EUV resist to prepare a negative image for patterning. This method to produce the “negative” image does not involve an etch back step and therefore accommodates the small resist budget. The material forming the “negative” image is sufficiently etch resistant, and may be significantly more etch resistant than the resist, which eliminates the need for an additional hard mask transfer layer.

In one aspect, the disclosure provides a method of forming a negative pattern mask. The method involves selectively depositing a metal oxide or metal nitride thin film in one or more features of a patterned EUV resist, for example a polymer-based chemically amplified resist (CAR) or a metal oxide resist such as those available from Inpria, Corvallis, Oreg., for example, on a semiconductor substrate, such that the deposition selectivity limits deposition to the layer of the substrate underlying the patterned resist that is exposed in the one or more features patterned in the resist, and not the resist. For example, the selective deposition may be conducted by a non-plasma thermal ALD process, since the plasma may damage the resist and plasma processes are susceptible to re-deposition, e.g., on the resist.

After selective deposition, the patterned resist may be removed to invert the pattern by leaving the metal oxide or metal nitride thin film on the underlying substrate layer surface as a negative pattern mask block. The removal of the resist may follow the selective deposition without an intervening processing operation, in particular an etch back.

After the mask formation, the substrate layer may be etched using the negative pattern mask block. According to various embodiments, the negative pattern mask block material is more selective than the resist to the substrate layer etch chemistry.

Further processing operations may follow, for example to propagate the etching achieved using the negative pattern mask block into additional underlying substrate layers.

In another aspect, an apparatus for forming a negative pattern mask can be used to implement such a process. The apparatus may include one or more processing chambers and a controller including instructions for forming a negative pattern mask. The instructions may include code for, in the one or more processing chambers, selectively depositing a metal oxide or metal nitride thin film in one or more features of a patterned EUV resist on a semiconductor substrate, such that the deposition selectivity limits deposition to the layer of the substrate underlying the patterned resist that is exposed in the one or more features patterned in the resist, and not the resist, and removing the resist to invert the pattern by leaving the metal oxide or metal nitride feature on the substrate surface as a negative pattern mask block.

These and other features and advantages of the disclosure will be described in more detail below with reference to the associated drawings.

### BRIEF DESCRIPTION OF THE DRAWINGS

FIGS. 1A-D illustrate a process flow including a method for a negative pattern mask formation in accordance with this disclosure.

FIGS. 2A-G illustrate a particular embodiment of negative pattern mask formation process in accordance with this disclosure.

FIG. 3 is a schematic diagram of an example process chamber for performing disclosed embodiments.

FIG. 4 is a schematic diagram of an example process tool for performing disclosed embodiments.

FIG. 5 is a schematic diagram of an example apparatus for performing disclosed embodiments.

FIG. 6 depicts a semiconductor process cluster architecture with deposition, etch and patterning modules that interface with a vacuum transfer module, suitable for implementation of processes described herein.

### DETAILED DESCRIPTION

Reference will now be made in detail to specific embodiments of the disclosure. Examples of the specific embodiments are illustrated in the accompanying drawings. While the disclosure will be described in conjunction with these specific embodiments, it will be understood that it is not intended to limit the disclosure to such specific embodiments. On the contrary, it is intended to cover alternatives, modifications, and equivalents as may be included within the spirit and scope of the disclosure. In the following description, numerous specific details are set forth in order to provide a thorough understanding of the present disclosure. The present disclosure may be practiced without some or all of these specific details. In other instances, well known process operations have not been described in detail so as to not unnecessarily obscure the present disclosure.

### INTRODUCTION

Extreme ultraviolet (EUV) lithography can extend lithography technology beyond its current resolution limits by moving to smaller imaging source wavelengths achievable with current photolithography methods. EUV light sources at approximately 10-20 nm, or 11-14 nm wavelength, for example 13.5 nm wavelength, can be used for leading-edge lithography tools, also referred to as scanners. The EUV radiation is strongly absorbed in a wide range of solid and fluid materials including quartz and water vapor, and so operates in a vacuum.

EUV lithography typically makes use of EUV resists that are polymer-based chemically amplified resists (CARs) produced by liquid-based spin-on techniques. Improvements in CARs have been made by reducing resist blur (acid diffusion) and pattern collapse by using thin films with high surface adhesion and structural integrity. Thin CARs, however, dictate process window and can increase complexity by necessitating the use of additional layers to support multi-step pattern transfer. In such cases, the pattern must be first transferred into a hard mask layer before subsequent transfer into the substrate.

The resist pattern is sometimes “inverted” by gapfilling the pattern with a spin-on or vapor deposited film with adequate etch contrast. According to this conventional process, the gapfill operation is followed by an etch back step to remove gapfill material from the field region of the resist prior to resist strip. This approach is taken when the lithographic image contrast is superior for the “positive” pattern but the actual need is for the “negative” pattern. Etch back steps have limited selectivity that can result in the gapfill feature being shorter than optimal for a mask. This becomes even more critical when the resist is very thin, as is typical for EUV resist.

Negative Pattern Mask Formation

This disclosure provides method and apparatus for processing a semiconductor substrate using a selective deposition process to deposit a metal oxide or metal nitride thin film in a feature defined in an EUV resist to prepare a negative image for patterning. This method to produce the “negative” image does not involve an etch back step and therefore accommodates the small resist budget available due to the relatively thin EUV resists. The material forming the “negative” image is sufficiently etch resistant, and may be significantly more etch resistant than the resist, which eliminates the need for an additional hard mask transfer layer.

The disclosure provides that a method of forming a negative pattern mask. The method involves selectively depositing a metal oxide or metal nitride thin film in one or more features of a patterned EUV resist, for example a polymer-based chemically amplified resist (CAR) or a metal oxide resist such as are available from Inpria, Corvallis, Oreg., for example, on a semiconductor substrate, such that the deposition selectivity limits deposition to the layer of the substrate underlying the patterned resist that is exposed in the one or more features patterned in the resist, and not the resist. For example, the selective deposition may be conducted by a non-plasma thermal ALD process, since the plasma may damage the resist and plasma processes are susceptible to re-deposition, e.g., on the resist.

After selective deposition, the patterned EUV resist may be removed to invert the pattern by leaving the metal oxide or metal nitride thin film on the underlying substrate layer surface as a negative pattern mask block. The removal of the resist may follow the selective deposition without an intervening processing operation, in particular an etch back.

After the mask formation, the substrate layer may be etched using the negative pattern mask block. According to various embodiments, the negative pattern mask block material is more selective than the resist to the substrate layer etch chemistry.

Further processing operations may follow, for example to propagate the etching achieved using the negative pattern mask block into additional underlying substrate layers.

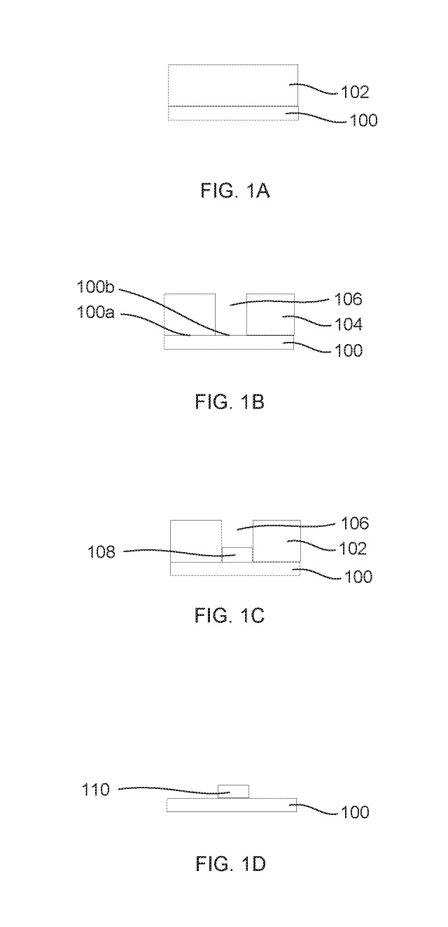

FIGS. 1A-D illustrate a process flow including a method for a negative pattern mask formation in accordance with this disclosure.

Referring to FIG. 1A, a portion of a semiconductor substrate 100 to be patterned is shown. In a typical example, the semiconductor substrate 100 is a silicon wafer including partially-formed integrated circuits formed by deposition and etch processes. In FIG. 1A, an EUV resist 102, such as a polymer-based chemically amplified resist (CAR) produced by liquid-based spin-on techniques, is depicted as deposited on the semiconductor substrate 100.

A review describing suitable CAR materials, characteristics and processing techniques is provided in A. S. Gangnaik, et al., New Generation Electron Beam Resists: A Review, Chem. Mater. 2017, 29, 1898-1917, which is incorporated herein by reference for this purpose.

In other embodiments, the EUV resist may be a metal oxide EUV resist such as are available from Inpria, Corvallis, Oreg.

The EUV resist is patterned in an EUV patterning tool as illustrated in FIG. 1B. Referring to FIG. 1B, the resist 102 is patterned by EUV lithography (EUVL) involving an EUV exposure followed by pattern development to form a “positive” pattern resist 104 on the substrate 100. Suitable EUVL techniques are known in the art, for example as discussed in Y. Fan, et al., Benchmarking Study of EUV Resists for NXE:3300B, Proc. of SPIE Vol. 9776 97760 W-1 (2016), which is incorporated herein by reference for this purpose.

It should be noted that a EUVL tool typically operates at a higher vacuum than a deposition tool. If this is the case, it is desirable to increase the vacuum environment of the substrate during the transfer from the deposition to the patterning tool to allow the substrate and deposited metal oxide-containing film to degas prior to entry into the patterning tool. This is so that the patterning tool optics do not become contaminated by outgassing from the substrate.

As shown in FIG. 1B, the patterned EUV resist 104 is a “positive” pattern with an unexposed substrate region 100a where the resist remains, and an exposed substrate region 100b where the resist was removed to form a pattern feature 106 in the resist following pattern development.

Referring to FIG. 1C, in accordance with this disclosure, the “positive” pattern in the EUV resist is reversed by selectively depositing in the pattern feature 106 a metal oxide or metal nitride thin film 108, for example having thickness of about 2 nm to 50 nm, for example 5 to 20 nm, such as about 5, 10, 15 or 20 nm. The deposition is conducted so that metal oxide or metal nitride thin film 108 is selectively deposited only on the substrate surface 100b and not the resist 102. In one embodiment, the selective deposition of the metal oxide or metal nitride thin film 108 is conducted on a silicon or silicon-containing substrate surface by a non-plasma thermal atomic layer deposition (ALD) process. Plasma processing has been found to be disfavored since the plasma may damage the resist and metal oxides can be deposited on resists using plasma processes; the chemical selectivity of the non-plasma, thermal deposition is degraded.

The deposition and etch selectivities of the selectively deposited metal oxide or metal nitride can be tailored to be differentiated from those of the CAR or metal oxide resist according to the principles of the method described herein, as would be apparent the a person of ordinary skill in the art given the disclosure provided herein and/or the information available from the provider of the metal oxide resist material, for example Inpria Corp.

According to a non-plasma thermal atomic layer deposition (ALD) process, the metal oxide or metal nitride will rapidly nucleate and deposit on a silicon substrate region, which has oxygen or hydroxyl groups on its surface. Where a CAR resist is used, the resist is composed of an organic material that does not have oxygen or hydroxyl groups on its surface to promote the deposition of the metal oxide or metal nitride. Therefore, the sides and top of the features patterned in the CAR will not support deposition, while the developed area will have a non-resist substrate (e.g., silicon) exposed which will hydroxyl groups and enable selective film growth.

Such an ALD operation may be conducted as described in co-pending U.S. application Ser. No. 15/432,634, titled Selective Deposition of Silicon Oxide, incorporated by reference herein for this purpose.

The selective deposition can be achieved by sequential exposure repeated for several cycles. Deposition rates can be about 0.1 Å/cycle to 1 Å/cycle, and between about 10-100 cycles can be performed until a metal oxide layer having desired thickness is deposited. Examples of suitable metal-containing precursors include halogenated metal-containing precursors (such as TiCl₄, and TiBr₄), and non-halogenated metal-containing precursors, such as organometallic compounds, which include alkyl substituted metal amides and the like. Specific examples of alkyl substituted amides that are suitable for ALD are tetrakis(dimethylamino) metal, and tetrakis(ethylmethylamino) metal. Oxygen-containing reactants include without limitation oxygen, ozone, water, hydrogen peroxide, NO or alcohol. Mixtures of oxygen-containing reactants can also be used. The deposition conditions will vary depending on the choice of ALD reactants, where more reactive precursors will generally react at lower temperatures than less reactive precursors. The processes typically will be carried out at a temperature of between about 20-100° C., e.g., 75° C., and at a subatmospheric pressure. The temperature and pressure are selected such that the reactants remain in the gaseous form in the process chamber to avoid condensation. Each reactant is provided to the process chamber in a gaseous form either alone or mixed with a carrier gas, such as argon, helium, or nitrogen. The flow rates of these mixtures will depend on the size of the process chamber, and are in some embodiments between about 10-10,000 sccm.

A suitable aminosilane has a chemical formula as follows:

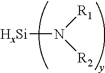

where x is an integer between and including 1 and 3, x+y=4 and each of R₁ and R₂ is hydrogen or an alkyl ligand. For example, in some embodiments, the aminosilane is monoaminosilane, which has the chemical structure:

H₃Si—NR₁R₂

where each of R₁ and R₂ is hydrogen or an alkyl ligand.

The aminosilane in some embodiments may be any of monoaminosilane, diaminosilane, triaminosilane, tetraaminosilane, and combinations thereof. Chemical structures for these examples are provided below:

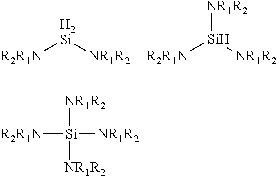

As noted above, R₁ and R₂ may be any alkyl ligand. In one example, the aminosilane may be N′N′-dimethylsilanediamine, having the structure:

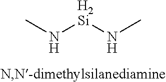

Other silicon-containing precursors include silicon alkoxides and silicon halides, which may be used in some embodiments.

Referring to FIG. 1D, following deposition of the metal oxide or metal nitride 108, the remaining patterned resist 104 is removed by a resist strip operation, for example as described in Table 5 of Chem. Mater. 2017, 29, 1898-1917, noted above, to invert the pattern, forming a negative pattern mask by leaving the metal oxide or metal nitride 108 on the substrate 100 surface as a negative pattern mask block 110. According to various embodiments, the negative pattern mask block material is more selective than the resist to the substrate etch.

In specific embodiments, as noted above, the substrate may be or include silicon and the exposed substrate surface has Si—O or Si—OH groups, whereas the CAR resist surface does not have —O or —OH groups. The oxide or nitride of a metal selected from the group consisting of Si, Hf, Sn and Zr, for example, is selectively deposited in the feature. Other metal oxides or nitrides meeting the deposition and etch selectivity criteria, such as transition or rare earth metals, including Al, Ti or Y, may also be used.

In one example, SiO₂ can be selectively deposited on a silicon substrate in the feature by thermal ALD using a monoamine silane precursor with O₃ as an oxidizing agent. Or HfO₂ can be selectively deposited on a silicon oxide substrate, e.g., a hardmask in the feature by thermal ALD using a hafnium amide with water as an oxidant.

In various aspects, the methods described here are particularly advantageous for deposition in small features, for example, when the width of the feature in the EUV resist is no more than 30 nm, such as may be typical in advanced node EUV lithography operations.

This method of forming a negative pattern mask can be conducted without an intervening processing operation between the selective deposition and resist removal operations. For example, the there is no need for an etch back operation to remove gapfill material from the field region of the resist prior to resist strip.

Following the formation of the negative pattern mask, the substrate may be etched using the negative pattern mask block.

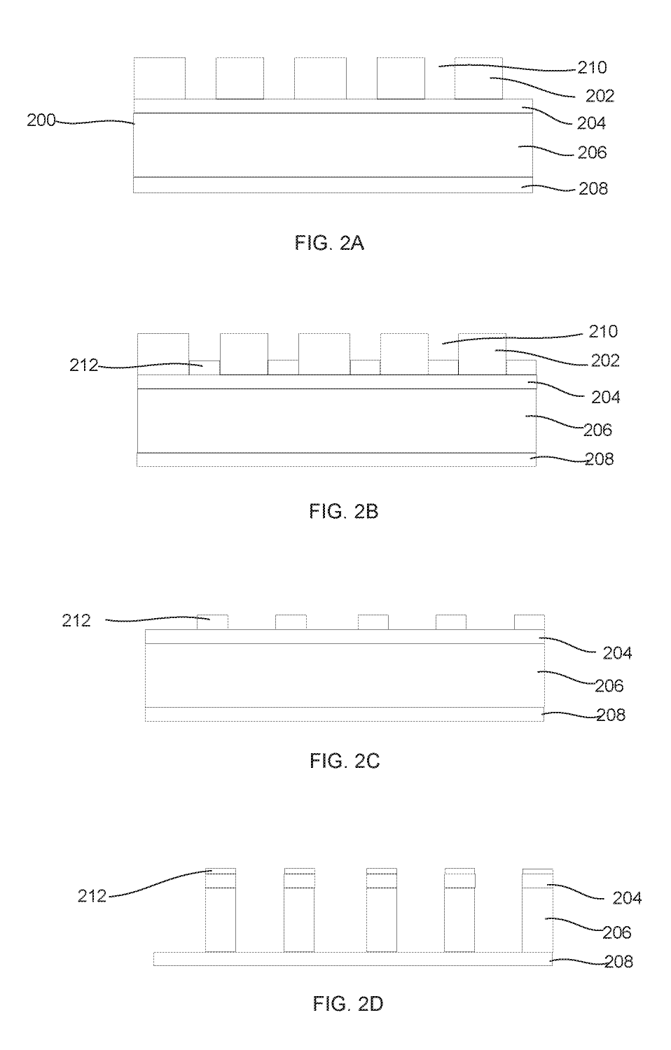

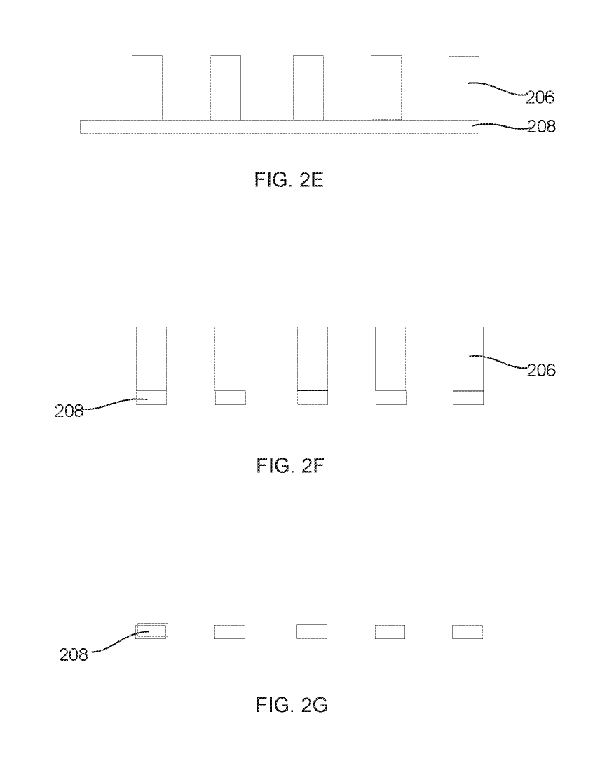

FIGS. 2A-G illustrate a particular embodiment of negative pattern mask formation process in accordance with this disclosure.

Referring to FIG. 2A, a semiconductor substrate 200 for processing operations as described herein is shown. The substrate 200 includes a plurality of layers in stack including a patterned EUV resist top layer 202, a bottom hardmask layer 206, generally carbon-based, and a target layer 208. In this embodiment, the EUV resist is a CAR, and the stack includes an optional middle layer 204 composed of a silicon-based dielectric, such a SiO₂, to separate the CAR resist and the carbon-based middle layer for selectivity to the EUV patterning operation that forms the patterned EUV resist. The target layer may be, for example, TiN.

In other embodiments, the polymer-based CAR EUV resist 202 may be replaced with a metal oxide EUV resist, such as are available from Inpria, Corvallis, Oreg. In such embodiments, the optional middle layer 204 is unnecessary since the etch selectivity of the metal oxide resist and bottom layer are readily differentiated.

The patterned EUV resist top layer 202 includes one or more features 210 wherein the underlying layer 204 of the substrate 200 is exposed. Referring to FIG. 2B, the “positive” pattern in the EUV resist is reversed by selectively depositing in the pattern feature 210 a metal oxide or metal nitride thin film 212. The deposition is conducted so that metal oxide or metal nitride thin film 212 is selectively deposited only on the substrate 204 surface and not the resist 202. The selective deposition of the metal oxide or metal nitride thin film 212 may be conducted on the silicon-containing middle layer 204 substrate surface by a non-plasma thermal atomic layer deposition (ALD) process, as described above. As noted above, the deposition and etch selectivities of the selectively deposited metal oxide or metal nitride can be tailored to be differentiated from those of the CAR EUV resist according to the principles of the method described herein, as would be apparent the a person of ordinary skill in the art given the disclosure provided herein.

Referring to FIG. 2C, following deposition of the metal oxide or metal nitride 212, the patterned resist 202 is removed by a resist strip operation to invert the pattern, forming a negative pattern mask by leaving the metal oxide or metal nitride on the substrate 200 surface as a negative pattern mask block 212. The metal oxide or metal nitride of the negative pattern mask block 212 is more selective than the former EUV resist to the chemistry to be used to etch the underlying optional middle layer 204 and bottom layer 206.

As shown in FIG. 2D, the negative pattern mask block 212 is then used to etch the optional middle layer 204 and bottom layer 206 to form a carbon-based hardmask. And, referring to FIG. 2E, the hardmask 206 is used to etch the target layer 208.

The resist strip and etch operations of the substrate layers depicted in FIGS. 2C-2F may be accomplished by conventional processes which would be apparent to one of ordinary skill in the art given the disclosure provided herein.

As noted above, the methods described here are particularly advantageous for deposition in small features, for example, when the width of the feature in the EUV resist is no more than 30 nm, such as may be typical in advanced node EUV lithography operations. The etched target layer, having etched features of no more than 30 nm, is shown in FIG. 2G.

Apparatus

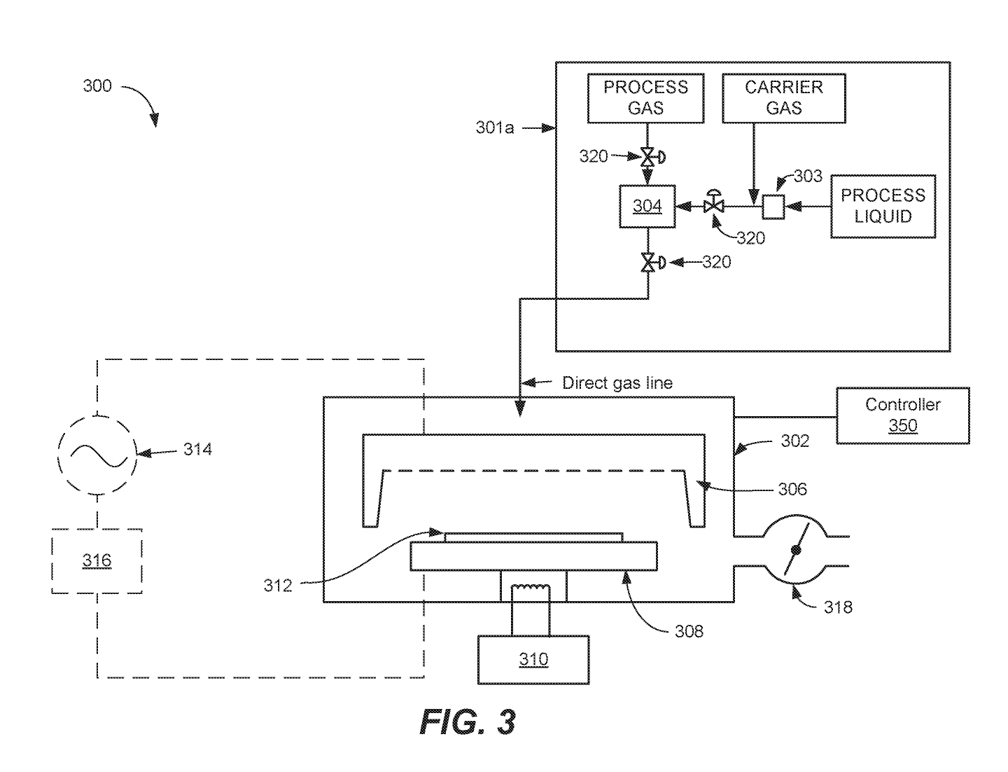

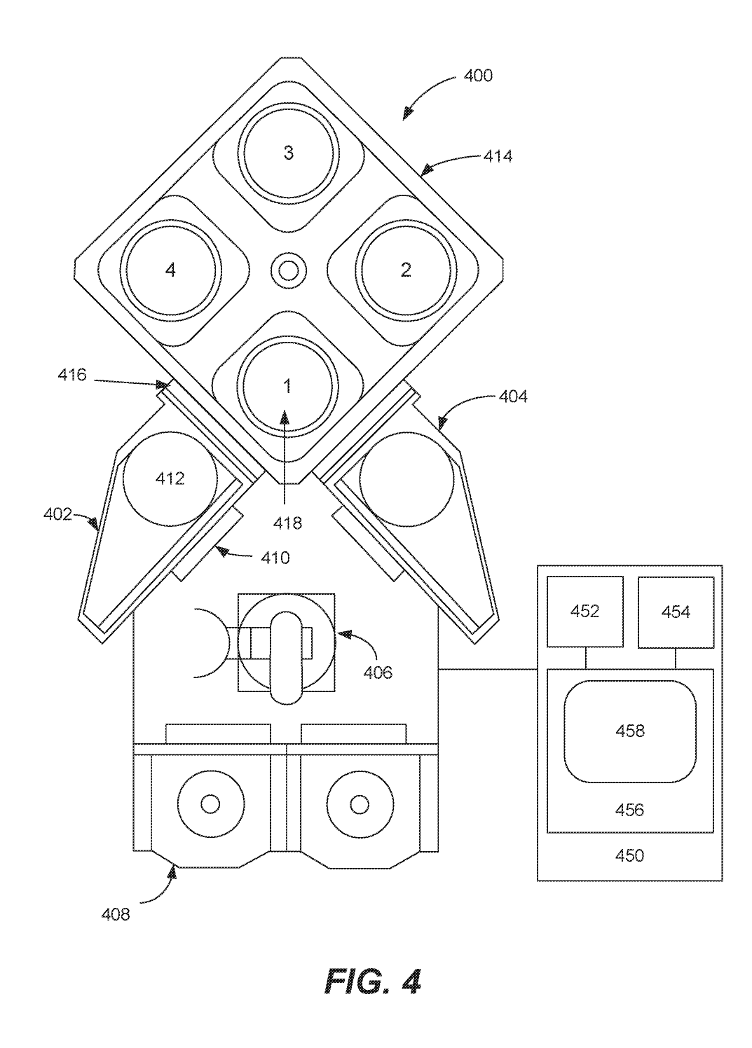

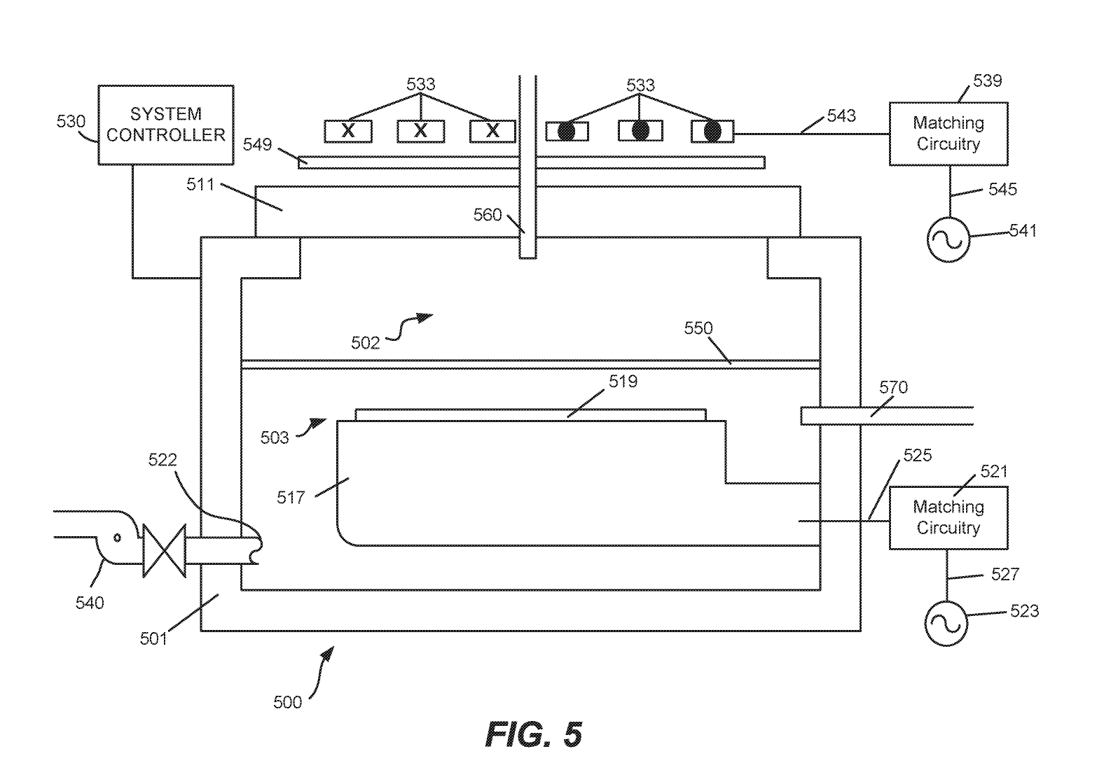

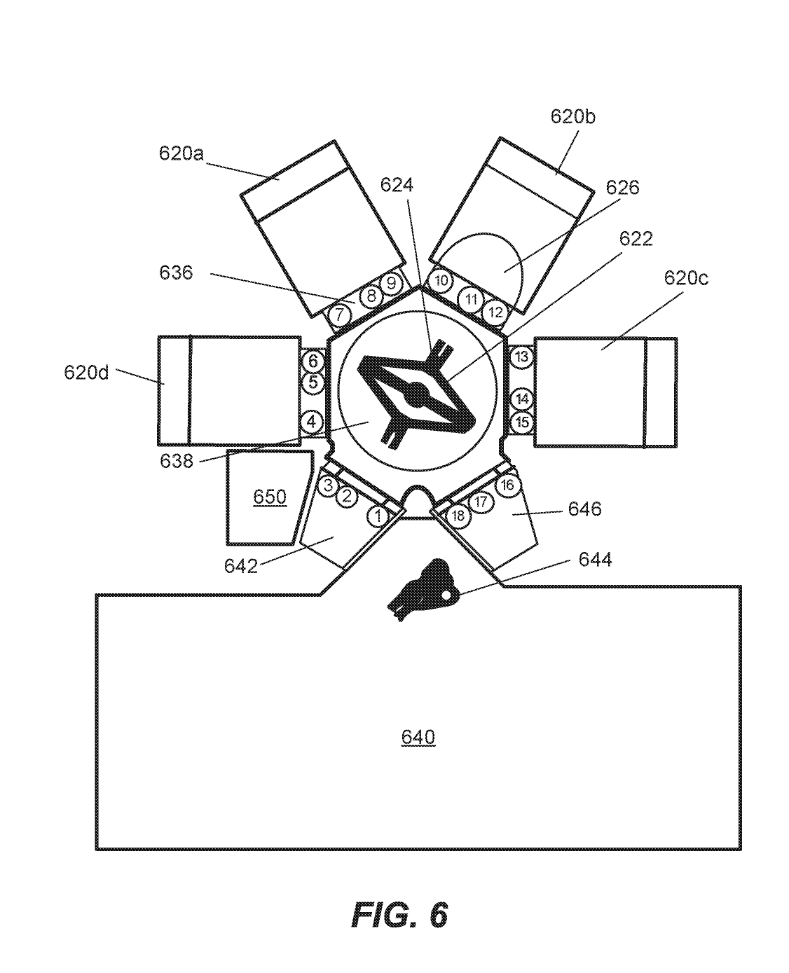

FIG. 3 depicts a schematic illustration of an embodiment of an atomic layer deposition (ALD) process station 300 having a process chamber body 302 for maintaining a low-pressure environment. A plurality of ALD process stations 300 may be included in a common low pressure process tool environment. For example, FIG. 4 depicts an embodiment of a multi-station processing tool 400, such as a VECTOR® processing tool available from Lam Research Corporation, Fremont, Calif. In some embodiments, one or more hardware parameters of ALD process station 300 including those discussed in detail below may be adjusted programmatically by one or more computer controllers 350. An ALD processing tool may be configured as a module in a cluster tool. FIG. 6 depicts a semiconductor process cluster tool architecture with vacuum-integrated deposition and patterning modules suitable for implementation of the processes described herein. Such a cluster process tool architecture can include etch and/or EUV patterning modules, as described further below with reference to FIGS. 5 and 6.

Returning to FIG. 3, ALD process station 300 fluidly communicates with reactant delivery system 301a for delivering process gases to a distribution showerhead 306. Reactant delivery system 301a includes a mixing vessel 304 for blending and/or conditioning process gases, such as an aminosilane precursor gas, or oxidizing agent gas (e.g., ozone), or ammonia and/or nitrogen gas, for delivery to showerhead 306. One or more mixing vessel inlet valves 320 may control introduction of process gases to mixing vessel 304. Where plasma deposition is used, nitrogen plasma and/or ammonia plasma may also be delivered to the showerhead 306 or may be generated in the ALD process station 300. As noted above, in at least some embodiments, non-plasma, thermal deposition is favored. Plasma deposition could be done if done at low temperature (e.g., less than 75° C.) and low power (e.g., less than 1000 W; 250 W per station for a four station system), such as is typically used for PEALD oxide with a carbon mandrel for patterning applications.

As an example, the embodiment of FIG. 3 includes a vaporization point 303 for vaporizing liquid reactant to be supplied to the mixing vessel 304. In some embodiments, vaporization point 303 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 303 may be heat traced. In some examples, mixing vessel 304 may also be heat traced. In one non-limiting example, piping downstream of vaporization point 303 has an increasing temperature profile extending from approximately 100° C. to approximately 150° C. at mixing vessel 304.

In some embodiments, liquid precursor or liquid reactant may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 303. In one scenario, a liquid injector may be mounted directly to mixing vessel 304. In another scenario, a liquid injector may be mounted directly to showerhead 306.

In some embodiments, a liquid flow controller (LFC) upstream of vaporization point 303 may be provided for controlling a mass flow of liquid for vaporization and delivery to process station 300. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 306 distributes process gases toward substrate 312. In the embodiment shown in FIG. 3, the substrate 312 is located beneath showerhead 306 and is shown resting on a pedestal 308. Showerhead 306 may have any suitable shape, and may have any suitable number and arrangement of ports for distributing process gases to substrate 312.

In some embodiments, pedestal 308 may be raised or lowered to expose substrate 312 to a volume between the substrate 312 and the showerhead 306. It will be appreciated that, in some embodiments, pedestal height may be adjusted programmatically by a suitable computer controller 350.

In another scenario, adjusting a height of pedestal 308 may allow a plasma density to be varied during plasma activation cycles in the process in embodiments where a plasma is ignited. At the conclusion of the process phase, pedestal 308 may be lowered during another substrate transfer phase to allow removal of substrate 312 from pedestal 308.

In some embodiments, pedestal 308 may be temperature controlled via heater 310. In some embodiments, the pedestal 308 may be heated to a temperature of greater than 50° C. but less than 100° C., for example 60 to 80° C., such as about 75° C., during deposition of silicon oxide or nitride films as described in disclosed embodiments.

Further, in some embodiments, pressure control for process station 300 may be provided by butterfly valve 318. As shown in the embodiment of FIG. 3, butterfly valve 318 throttles a vacuum provided by a downstream vacuum pump (not shown). However, in some embodiments, pressure control of process station 300 may also be adjusted by varying a flow rate of one or more gases introduced to the process station 300.

In some embodiments, a position of showerhead 306 may be adjusted relative to pedestal 308 to vary a volume between the substrate 312 and the showerhead 306. Further, it will be appreciated that a vertical position of pedestal 308 and/or showerhead 306 may be varied by any suitable mechanism within the scope of the present disclosure. In some embodiments, pedestal 308 may include a rotational axis for rotating an orientation of substrate 312. It will be appreciated that, in some embodiments, one or more of these example adjustments may be performed programmatically by one or more suitable computer controllers 350.

Where plasma may be used, for example in etch operations conducted in the same chamber, showerhead 306 and pedestal 308 electrically communicate with a radio frequency (RF) power supply 314 and matching network 316 for powering a plasma. In some embodiments, the plasma energy may be controlled by controlling one or more of a process station pressure, a gas concentration, an RF source power, an RF source frequency, and a plasma power pulse timing. For example, RF power supply 314 and matching network 316 may be operated at any suitable power to form a plasma having a desired composition of radical species. Examples of suitable powers are about 150 W to about 6000 W. Plasma may be used during treatment of a silicon nitride surface prior to selective deposition of silicon oxide on silicon oxide relative to silicon nitride. RF power supply 314 may provide RF power of any suitable frequency. In some embodiments, RF power supply 314 may be configured to control high- and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 2.45 GHz, or greater than about 13.56 MHz, or greater than 27 MHz, or greater than 40 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 350 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or an ammonia and/or nitrogen reactant gas, instructions for setting a flow rate of a carrier gas (such as argon), and time delay instructions for the first recipe phase. A second recipe phase may include instructions for setting a flow rate of an inert and/or aminosilane silicon precursor gas, instructions for setting a flow rate of a carrier gas (such as argon), and time delay instructions for a second recipe phase. A third, subsequent recipe phase may include instructions for modulating or stopping a flow rate of an inert and/or a reactant gas, and instructions for modulating a flow rate of a carrier or purge gas and time delay instructions for the third recipe phase. A fourth recipe phase may include instructions for modulating a flow rate of an oxidizing agent gas such as ozone, instructions for modulating the flow rate of a carrier or purge gas, and time delay instructions for the fourth recipe phase. A fifth, subsequent recipe phase may include instructions for modulating or stopping a flow rate of an inert and/or a reactant gas, and instructions for modulating a flow rate of a carrier or purge gas and time delay instructions for the fifth recipe phase. It will be appreciated that these recipe phases may be further subdivided and/or iterated in any suitable way within the scope of the disclosed embodiments. In some embodiments, the controller 350 may include any of the features described below with respect to system controller 350 of FIG. 3.

As described above, one or more process stations may be included in a multi-station processing tool. FIG. 4 shows a schematic view of an embodiment of a multi-station processing tool 400 with an inbound load lock 402 and an outbound load lock 404, either or both of which may include a remote plasma source. A robot 406 at atmospheric pressure is configured to move wafers from a cassette loaded through a pod 408 into inbound load lock 402 via an atmospheric port 410. A wafer is placed by the robot 406 on a pedestal 412 in the inbound load lock 402, the atmospheric port 410 is closed, and the load lock is pumped down. Where the inbound load lock 402 includes a remote plasma source, the wafer may be exposed to a remote plasma treatment to treat the silicon nitride surface in the load lock prior to being introduced into a processing chamber 414. Further, the wafer also may be heated in the inbound load lock 402 as well, for example, to remove moisture and adsorbed gases. Next, a chamber transport port 416 to processing chamber 414 is opened, and another robot (not shown) places the wafer into the reactor on a pedestal of a first station shown in the reactor for processing. While the embodiment depicted in FIG. 4 includes load locks, it will be appreciated that, in some embodiments, direct entry of a wafer into a process station may be provided.

The depicted processing chamber 414 includes four process stations, numbered from 1 to 4 in the embodiment shown in FIG. 4. Each station has a heated pedestal (shown at 418 for station 1), and gas line inlets. It will be appreciated that in some embodiments, each process station may have different or multiple purposes. For example, in some embodiments, a process station may be switchable between an ALD and plasma-enhanced ALD process mode.

Additionally or alternatively, in some embodiments, processing chamber 414 may include one or more matched pairs of ALD and plasma-enhanced ALD process stations. While the depicted processing chamber 414 includes four stations, it will be understood that a processing chamber according to the present disclosure may have any suitable number of stations. For example, in some embodiments, a processing chamber may have five or more stations, while in other embodiments a processing chamber may have three or fewer stations.

FIG. 4 depicts an embodiment of a wafer handling system 490 for transferring wafers within processing chamber 414. In some embodiments, wafer handling system 490 may transfer wafers between various process stations and/or between a process station and a load lock. It will be appreciated that any suitable wafer handling system may be employed. Non-limiting examples include wafer carousels and wafer handling robots. FIG. 4 also depicts an embodiment of a system controller 450 employed to control process conditions and hardware states of process tool 400. System controller 450 may include one or more memory devices 456, one or more mass storage devices 454, and one or more processors 452. Processor 452 may include a CPU or computer, analog, and/or digital input/output connections, stepper motor controller boards, etc.

In some embodiments, system controller 450 controls all of the activities of process tool 400. System controller 450 executes system control software 458 stored in mass storage device 454, loaded into memory device 456, and executed on processor 452. Alternatively, the control logic may be hard coded in the controller 450. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 458 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 400. System control software 458 may be configured in any suitable way. For example, various process tool component subroutines or control objects may be written to control operation of the process tool components used to carry out various process tool processes. System control software 458 may be coded in any suitable computer readable programming language.

In some embodiments, system control software 458 may include input/output control (IOC) sequencing instructions for controlling the various parameters described above. Other computer software and/or programs stored on mass storage device 454 and/or memory device 456 associated with system controller 450 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 418 and to control the spacing between the substrate and other parts of process tool 400.

A process gas control program may include code for controlling gas composition (e.g., aminosilane gases, and oxidizing agent gases, ammonia, nitrogen, carrier gases and/or purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 450. The user interface may include a display screen, graphical software displays of the apparatus and/or process conditions, and user input devices such as pointing devices, keyboards, touch screens, microphones, etc.

In some embodiments, parameters adjusted by system controller 450 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 450 from various process tool sensors. The signals for controlling the process may be output on the analog and digital output connections of process tool 400. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 450 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 450 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 450.

In some implementations, the system controller 450 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 450, depending on the processing conditions and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 450 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 450 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 450, in some implementations, may be a part of or coupled to a computer that is integrated with, coupled to the system, otherwise networked to the system, or a combination thereof. For example, the system controller 450 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 450 receives instructions in the form of data, which specify parameters for each of the processing steps to be performed during one or more operations. It should be understood that the parameters may be specific to the type of process to be performed and the type of tool that the system controller 450 is configured to interface with or control. Thus as described above, the system controller 450 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 450 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.
Inductively coupled plasma (ICP) reactors which, in certain embodiments, may be suitable for strip and etch operations suitable for implementation of some embodiments, are now described. Although ICP reactors are described herein, in some embodiments, it should be understood that capacitively coupled plasma reactors may also be used.

FIG. 5 schematically shows a cross-sectional view of an inductively coupled plasma apparatus 200 appropriate for implementing certain embodiments or aspects of embodiments such as etch, strip or deposition herein, an example of which is a Kiyo® reactor, produced by Lam Research Corp. of Fremont, Calif. The inductively coupled plasma apparatus 500 includes an overall process chamber 524 structurally defined by chamber walls 501 and a window 511. The chamber walls 501 may be fabricated from stainless steel or aluminum. The window 511 may be fabricated from quartz or other dielectric material. An optional internal plasma grid 550 divides the overall process chamber into an upper sub-chamber 502 and a lower sub chamber 503. In most embodiments, plasma grid 550 may be removed, thereby utilizing a chamber space made of sub chambers 502 and 503. A chuck 517 is positioned within the lower sub-chamber 503 near the bottom inner surface. The chuck 517 is configured to receive and hold a semiconductor wafer 519 upon which the etching and deposition processes are performed. The chuck 517 can be an electrostatic chuck for supporting the wafer 519 when present. In some embodiments, an edge ring (not shown) surrounds chuck 517, and has an upper surface that is approximately planar with a top surface of the wafer 519, when present over chuck 517. The chuck 517 also includes electrostatic electrodes for chucking and dechucking the wafer 519. A filter and DC clamp power supply (not shown) may be provided for this purpose. Other control systems for lifting the wafer 519 off the chuck 517 can also be provided. The chuck 517 can be electrically charged using an RF power supply 523. The RF power supply 523 is connected to matching circuitry 521 through a connection 527. The matching circuitry 521 is connected to the chuck 517 through a connection 525. In this manner, the RF power supply 523 is connected to the chuck 517. In various embodiments, a bias power of the electrostatic chuck may be set at about 50V or may be set at a different bias power depending on the process performed in accordance with disclosed embodiments. For example, the bias power may be between about 20 Vb and about 100 V, or between about 30 V and about 150 V.

Elements for plasma generation include a coil 533 is positioned above window 511. In some embodiments, a coil is not used in disclosed embodiments. The coil 533 is fabricated from an electrically conductive material and includes at least one complete turn. The example of a coil 533 shown in FIG. 5 includes three turns. The cross sections of coil 533 are shown with symbols, and coils having an “X” extend rotationally into the page, while coils having a “•” extend rotationally out of the page. Elements for plasma generation also include an RF power supply 541 configured to supply RF power to the coil 533. In general, the RF power supply 541 is connected to matching circuitry 539 through a connection 545. The matching circuitry 539 is connected to the coil 533 through a connection 543. In this manner, the RF power supply 541 is connected to the coil 533. An optional Faraday shield 549a is positioned between the coil 533 and the window 511. The Faraday shield 549a may be maintained in a spaced apart relationship relative to the coil 533. In some embodiments, the Faraday shield 549a is disposed immediately above the window 511. In some embodiments, the Faraday shield 549b is between the window 511 and the chuck 517. In some embodiments, the Faraday shield 549b is not maintained in a spaced apart relationship relative to the coil 533. For example, the Faraday shield 549b may be directly below the window 511 without a gap. The coil 533, the Faraday shield 549a, and the window 511 are each configured to be substantially parallel to one another. The Faraday shield 549a may prevent metal or other species from depositing on the window 511 of the process chamber 524.

Process gases may be flowed into the process chamber through one or more main gas flow inlets 560 positioned in the upper sub-chamber 502 and/or through one or more side gas flow inlets 570. Likewise, though not explicitly shown, similar gas flow inlets may be used to supply process gases to a capacitively coupled plasma processing chamber. A vacuum pump, e.g., a one or two stage mechanical dry pump and/or turbomolecular pump 540, may be used to draw process gases out of the process chamber 524 and to maintain a pressure within the process chamber 524. For example, the vacuum pump may be used to evacuate the lower sub-chamber 503 during a purge operation of ALD. A valve-controlled conduit may be used to fluidically connect the vacuum pump to the process chamber 524 so as to selectively control application of the vacuum environment provided by the vacuum pump. This may be done employing a closed loop-controlled flow restriction device, such as a throttle valve (not shown) or a pendulum valve (not shown), during operational plasma processing. Likewise, a vacuum pump and valve controlled fluidic connection to the capacitively coupled plasma processing chamber may also be employed.

During operation of the apparatus 500, one or more process gases may be supplied through the gas flow inlets 560 and/or 570. In certain embodiments, process gas may be supplied only through the main gas flow inlet 560, or only through the side gas flow inlet 570. In some cases, the gas flow inlets shown in the figure may be replaced by more complex gas flow inlets, one or more showerheads, for example. The Faraday shield 549a and/or optional grid 550 may include internal channels and holes that allow delivery of process gases to the process chamber 524. Either or both of Faraday shield 549a and optional grid 550 may serve as a showerhead for delivery of process gases. In some embodiments, a liquid vaporization and delivery system may be situated upstream of the process chamber 524, such that once a liquid reactant or precursor is vaporized, the vaporized reactant or precursor is introduced into the process chamber 524 via a gas flow inlet 560 and/or 570.

Radio frequency power is supplied from the RF power supply 541 to the coil 533 to cause an RF current to flow through the coil 533. The RF current flowing through the coil 533 generates an electromagnetic field about the coil 533. The electromagnetic field generates an inductive current within the upper sub-chamber 502. The physical and chemical interactions of various generated ions and radicals with the wafer 519 etch features of and selectively deposit layers on the wafer 519.

If the plasma grid 550 is used such that there is both an upper sub-chamber 502 and a lower sub-chamber 503, the inductive current acts on the gas present in the upper sub-chamber 502 to generate an electron-ion plasma in the upper sub-chamber 502. The optional internal plasma grid 550 limits the amount of hot electrons in the lower sub-chamber 503. In some embodiments, the apparatus 500 is designed and operated such that the plasma present in the lower sub-chamber 503 is an ion-ion plasma.

Both the upper electron-ion plasma and the lower ion-ion plasma may contain positive and negative ions, though the ion-ion plasma will have a greater ratio of negative ions to positive ions. Volatile etching and/or deposition byproducts may be removed from the lower sub-chamber 503 through port 522. The chuck 517 disclosed herein may operate at elevated temperatures ranging between about 10° C. and about 250° C. The temperature will depend on the process operation and specific recipe.

Apparatus 500 may be coupled to facilities (not shown) when installed in a clean room or a fabrication facility. Facilities include plumbing that provide processing gases, vacuum, temperature control, and environmental particle control. These facilities are coupled to apparatus 500, when installed in the target fabrication facility. Additionally, apparatus 500 may be coupled to a transfer chamber that allows robotics to transfer semiconductor wafers into and out of apparatus 500 using typical automation.

In some embodiments, a system controller 530 (which may include one or more physical or logical controllers) controls some or all of the operations of a process chamber 524. The system controller 530 may include one or more memory devices and one or more processors. In some embodiments, the apparatus 500 includes a switching system for controlling flow rates and durations when disclosed embodiments are performed. In some embodiments, the apparatus 500 may have a switching time of up to about 500 ms, or up to about 750 ms. Switching time may depend on the flow chemistry, recipe chosen, reactor architecture, and other factors.

In some implementations, the system controller 530 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 530, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 530 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 530, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 530 receives instructions in the form of data, which specify parameters for each of the processing steps to be performed during one or more operations. It should be understood that the parameters may be specific to the type of process to be performed and the type of tool that the controller is configured to interface with or control. Thus as described above, the system controller 530 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

EUVL patterning may be conducted using any suitable tool, often referred to as a scanner, for example the TWINSCAN NXE: 3300B® platform supplied by ASML of Veldhoven, NL). The EUVL patterning tool may be a standalone device from which the substrate is moved into and out of for deposition and etching as described herein. Or, as described below, the EUVL patterning tool may be a module on a larger multi-component tool. FIG. 6 depicts a semiconductor process cluster tool architecture with vacuum-integrated deposition and patterning modules that interface with a vacuum transfer module, suitable for implementation of the processes described herein. While the processes may be conducted without such vacuum integrated apparatus, such apparatus may be advantageous in some implementations.

FIG. 6 depicts a semiconductor process cluster tool architecture with vacuum-integrated deposition and patterning modules that interface with a vacuum transfer module, suitable for implementation of the processes described herein. The arrangement of transfer modules to “transfer” wafers among multiple storage facilities and processing modules may be referred to as a “cluster tool architecture” system. Deposition and patterning modules are vacuum-integrated, in accordance with the requirements of a particular process. Other modules, such as for etch, may also be included on the cluster.

A vacuum transport module (VTM) 638 interfaces with four processing modules 620a-620d, which may be individually optimized to perform various fabrication processes. By way of example, processing modules 620a-620d may be implemented to perform deposition, evaporation, ELD, etch, strip, and/or other semiconductor processes. For example, module 620a may be an ALD reactor that may be operated to perform in a non-plasma, thermal atomic layer depositions as described herein, such as Vector tool, available from Lam Research Corporation, Fremont, Calif. And module 620b may be a PECVD tool, such as the Lam Vector®. It should be understood that the figure is not necessarily drawn to scale.

Airlocks 642 and 646, also known as a loadlocks or transfer modules, interface with the VTM 638 and a patterning module 640. For example, as noted above, a suitable patterning module may be the TWINSCAN NXE: 3300B® platform supplied by ASML of Veldhoven, NL). This tool architecture allows for work pieces, such as semiconductor substrates or wafers, to be transferred under vacuum so as not to react before exposure. Integration of the deposition modules with the lithography tool is facilitated by the fact that EUVL also requires a greatly reduced pressure given the strong optical absorption of the incident photons by ambient gases such as H₂O, O₂, etc.

As noted above, this integrated architecture is just one possible embodiment of a tool for implementation of the described processes. The processes may also be implemented with a more conventional stand-alone EUVL scanner and a deposition reactor, such as a Lam Vector tool, either stand alone or integrated in a cluster architecture with other tools, such as etch, strip etc. (e.g., Lam Kiyo or Gamma tools), as modules, for example as described with reference to FIG. 6 but without the integrated patterning module.

Airlock 642 may be an “outgoing” loadlock, referring to the transfer of a substrate out from the VTM 638 serving a deposition module 620a to the patterning module 640, and airlock 646 may be an “ingoing” loadlock, referring to the transfer of a substrate from the patterning module 640 back in to the VTM 638. The ingoing loadlock 646 may also provide an interface to the exterior of the tool for access and egress of substrates. Each process module has a facet that interfaces the module to VTM 638. For example, deposition process module 620a has facet 636. Inside each facet, sensors, for example, sensors 1-18 as shown, are used to detect the passing of wafer 626 when moved between respective stations. Patterning module 640 and airlocks 642 and 646 may be similarly equipped with additional facets and sensors, not shown.

Main VTM robot 622 transfers wafer 626 between modules, including airlocks 642 and 646. In one embodiment, robot 622 has one arm, and in another embodiment, robot 622 has two arms, where each arm has an end effector 624 to pick wafers such as wafer 626 for transport. Front-end robot 644, in is used to transfer wafers 626 from outgoing airlock 642 into the patterning module 640, from the patterning module 640 into ingoing airlock 646. Front-end robot 644 may also transport wafers 626 between the ingoing loadlock and the exterior of the tool for access and egress of substrates. Because ingoing airlock module 646 has the ability to match the environment between atmospheric and vacuum, the wafer 626 is able to move between the two pressure environments without being damaged.

It should be noted that a EUVL tool typically operates at a higher vacuum than a deposition tool. If this is the case, it is desirable to increase the vacuum environment of the substrate during the transfer between the deposition to the EUVL tool to allow the substrate to degas prior to entry into the patterning tool. Outgoing airlock 642 may provide this function by holding the transferred wafers at a lower pressure, no higher than the pressure in the patterning module 640, for a period of time and exhausting any off-gassing, so that the optics of the patterning tool 640 are not contaminated by off-gassing from the substrate. A suitable pressure for the outgoing, off-gassing airlock is no more than 1E-8 Torr.

In some embodiments, a system controller 650 (which may include one or more physical or logical controllers) controls some or all of the operations of the cluster tool and/or its separate modules. It should be noted that the controller can be local to the cluster architecture, or can be located external to the cluster architecture in the manufacturing floor, or in a remote location and connected to the cluster architecture via a network. The system controller 650 may include one or more memory devices and one or more processors. The processor may include a central processing unit (CPU) or computer, analog and/or digital input/output connections, stepper motor controller boards, and other like components. Instructions for implementing appropriate control operations are executed on the processor. These instructions may be stored on the memory devices associated with the controller or they may be provided over a network. In certain embodiments, the system controller executes system control software.

The system control software may include instructions for controlling the timing of application and/or magnitude of any aspect of tool or module operation. System control software may be configured in any suitable way. For example, various process tool component subroutines or control objects may be written to control operations of the process tool components necessary to carry out various process tool processes. System control software may be coded in any suitable compute readable programming language. In some embodiments, system control software includes input/output control (IOC) sequencing instructions for controlling the various parameters described above. For example, each phase of a semiconductor fabrication process may include one or more instructions for execution by the system controller. The instructions for setting process conditions for condensation, deposition, evaporation, patterning and/or etching phase may be included in a corresponding recipe phase, for example.

In various embodiments, an apparatus for forming a negative pattern mask is provided. The apparatus may include a processing chamber for patterning, deposition and etch, and a controller including instructions for forming a negative pattern mask. The instructions may include code for, in the processing chamber, patterning a feature in a chemically amplified (CAR) resist on a semiconductor substrate by EUV exposure to expose a surface of the substrate, selectively depositing in the feature a metal oxide or metal nitride in the feature such that the deposition selectivity limits deposition to the substrate surface and not the resist, and removing the resist to invert the pattern by leaving the metal oxide or metal nitride feature on the substrate surface as a negative pattern mask block.

The instructions may further include code for wherein according to the instructions the removal of the resist follows the selective deposition in the feature without an intervening processing operation, such as an etch back. The instructions may further include code for etching the substrate using the negative pattern mask block. The instructions may further include code, wherein according to the instructions, the selective deposition is conducted by a non-plasma thermal ALD process.

It should be noted that the computer controlling the wafer movement can be local to the cluster architecture, or can be located external to the cluster architecture in the manufacturing floor, or in a remote location and connected to the cluster architecture via a network. A controller as described above with respect to any of FIG. 3, 4 or 5 may be implemented with the tool in FIG. 6.

### CONCLUSION

Process and apparatus for forming a negative patterning mask in the context of EUV patterning uses a selective deposition process to deposit a metal oxide or metal nitride thin film in a feature defined in an EUV resist to prepare a negative image for patterning. The method to produce the “negative” image does not involve an etch back step and therefore accommodates the small resist budget. The material forming the “negative” image is significantly more etch resistant than resist which eliminates the need for an additional hard mask transfer layer.

It is understood that the examples and embodiments described herein are for illustrative purposes only and that various modifications or changes in light thereof will be suggested to persons skilled in the art. Although various details have been omitted for clarity's sake, various design alternatives may be implemented. Therefore, the present examples are to be considered as illustrative and not restrictive, and the disclosure is not to be limited to the details given herein, but may be modified within the scope of the appended claims.

What is claimed is:

1. A method of forming a negative pattern mask on a semiconductor substrate, comprising:
(a) selectively depositing a metal oxide or metal nitride thin film in one or more features of an EUV-patterned resist on a semiconductor substrate, the patterned resist exposing a surface of a substrate layer underlying the patterned resist, such that the deposition is selectively limited to the exposed substrate layer surface and not the resist; and
(b) removing the patterned EUV resist to invert the pattern by leaving the metal oxide or metal nitride thin film on the substrate layer surface as a negative pattern mask block.

2. The method of claim 1, wherein (b) follows (a) without an intervening processing operation.

3. The method of claim 2, further comprising etching the substrate layer underlying the patterned resist using the negative pattern mask block.

4. The method of claim 3, wherein the negative pattern mask block material is more selective to the etch process than the resist.

5. The method of claim 4, wherein the selective deposition is conducted by a non-plasma thermal ALD process.

6. The method of claim 5, wherein the resist is a chemically amplified resist (CAR) substrate comprises Si and the exposed substrate surface has Si—O or Si—OH groups.

7. The method of claim 6, wherein the CAR surface does not have —O or —OH groups.

8. The method of claim 7, wherein an oxide or nitride of a metal selected from the group consisting of Si, Hf, Sn, Ti, Al, Y and Zr, is selectively deposited in the feature.

9. The method of claim 7, wherein SiO₂ is selectively deposited in the feature.

10. The method of claim 9, wherein the thermal ALD uses a monoamine silane precursor with O₃ as an oxidizing agent.

11. The method of claim 7, wherein HfO₂ is selectively deposited in the feature.

12. The method of claim 11, wherein the thermal ALD uses a hafnium amide with water as an oxidant.

13. The method of claim 6, wherein the semiconductor substrate exposed is Si.

14. The method of claim 6, wherein the semiconductor substrate exposed is SiO.

15. The method of claim 6, wherein the semiconductor substrate exposed is a hardmask.

16. The method of claim 1, wherein the one or more features has a width of no more than 30 nm.

17. An apparatus for forming a negative pattern mask, the apparatus comprising:
one or more processing chambers;
a controller including instructions for forming a negative pattern mask, the instructions comprising code for:
in the one or more processing chambers:
(a) selectively depositing a metal oxide or metal nitride thin film in one or more features of a patterned EUV resist on a semiconductor substrate, such that the deposition selectivity limits deposition to the layer of the substrate underlying the patterned resist that is exposed in the one or more features patterned in the resist, and not the resist; and
(b) removing the resist to invert the pattern by leaving the metal oxide or metal nitride feature on the substrate surface as a negative pattern mask block.

18. The apparatus of claim 17, wherein according to the instructions, (b) follows (a) without an intervening processing operation.

19. The apparatus of claim 18, wherein the instructions further comprise code for etching the substrate using the negative pattern mask block.

20. The apparatus of claim 18, wherein according to the instructions, the selective deposition is conducted by a non-plasma thermal ALD process.
